(19) United States
(12) Patent Application Publication
(10) Pub. No.: US 2009/0261465 A1
(43) Pub. Date: Oct. 22, 2009

(54) SEMICONDUCTOR DEVICE AND ITS MANUFACTURING METHOD

(76) Inventor: Masatoshi SHINAGAWA, Shiga (JP)

Correspondence Address: MCDERMOTT WILL & EMERY LLP, 600 13TH STREET, NW, WASHINGTON, DC, 20005-3096, US

(21) Appl. No.: 12/411,734

(22) Filed: Mar. 26, 2009

(30) Foreign Application Priority Data
Apr. 17, 2008 (JP) 2008-107917
Feb. 13, 2009 (JP) 2009-031361

(51) Int. Cl. H01L 23/538; H01L 21/50

(52) U.S. Cl. 257/686; 438/119; 257/E21.499; 257/E23.169

(57) ABSTRACT

A semiconductor device includes a substrate having a substrate wiring, a semiconductor chip provided on the substrate, a first electrical conductor electrically connecting the semiconductor chip and the substrate wiring, and an electrically conductive pad provided on the substrate. The semiconductor device further includes a wiring member electrically connected to the electrically conductive pad and serving as a wiring path different from the substrate wiring.

### CROSS REFERENCE TO RELATED APPLICATIONS

This application claims priority under 35 U.S.C. §119(a) on Patent Application No. 2008-107917 filed in Japan on Apr. 17, 2008, and Patent Application No. 2009-031361 filed in Japan on Feb. 13, 2009, the entire contents of which are hereby incorporated by reference.

### BACKGROUND

As smaller sizes and higher performance are required for various electronic devices, such as a mobile telephone, a digital still camera and the like, there is an increasing demand for a more advanced packaging technique for semiconductor devices that supports higher performance, a higher processing speed, lower cost, a shorter development period, and the like. Examples of such advanced packaging techniques include a Package-on-Package (PoP) that allows stacking semiconductor packages in a semiconductor device as shown in FIG. 23.

Here, a semiconductor package shown in FIG. 23 will be briefly described.

The semiconductor package of FIG. 23 has a structure in which an upper package 50 is stacked on a lower package 10 (PoP structure) with solder balls 51 being interposed therebetween. The solder balls 51 are connected onto surface substrate wirings 11 provided on the lower package 10.

The lower package 10 includes a three-layer resin substrate 20. On the three-layer resin substrate 20, the surface substrate wirings 11, interlayer wirings 15 and rear-surface substrate wirings 13, and via holes 12 connecting these wirings are formed (wiring structure). A semiconductor chip 21 is fixed to an upper surface of the lower package 10 using an adhesive sheet 23. Here, the semiconductor chip 21 and the lower package 10 are electrically connected via the surface substrate wirings 11 and gold bumps 22 provided thereon. Also, solder balls 14 are provided on the rear-surface substrate wirings 13.

In the upper package 50, semiconductor chips 54 and 55 are stacked and fixed onto a resin substrate 60 using an adhesive sheet 56, and are sealed with a mold sealing resin 52. Here, substrate wirings 57 are provided on the resin substrate 60. Some of the substrate wirings 57 are electrically connected to the semiconductor chip 54 via bonding wires 59, while the others of the substrate wirings 57 are electrically connected to the semiconductor chip 55 via gold bumps 58.

The upper package 50 and the lower package 10 are separately and independently assembled, and thereafter, are electrically connected via the solder balls 51 by a reflow process.

In such a PoP semiconductor device, warpage may occur in the stacked upper and lower packages in opposite directions, leading to poor contact (poor connection) of a solder ball. To avoid this, Japanese Unexamined Patent Application Publication No. 2007-123454 (Document 1) discloses that a structure in which semiconductor packages are stacked can be changed to that using a tape substrate.

### SUMMARY

However, packages that are stacked in a PoP structure are often manufactured by different manufacturers, i.e., are separately optimized when assembled. Therefore, a problem that makes it difficult to employ the structure of Document 1 arises as follows.

Firstly, for a manufacturer that manufactures the upper package, more versatile products can be manufactured when a resin substrate is employed than when a tape substrate is employed as disclosed in Document 1. The use of a tape substrate is also disadvantageous in terms of cost. Also, as disclosed in Document 1, when semiconductor chips are stacked using solder balls, a voltage drops with an increase in the number of solder balls. Therefore, the technique of Document 1 is disadvantageous in terms of electrical characteristics, as compared to a technique of directly stacking semiconductor chips and connecting them by wire bonding as shown in FIG. 23.

Therefore, it is not desirable to employ the technique of Document 1 for the purpose of manufacture of the upper package.

Next, for a manufacturer that manufactures the lower package, it is complicated to arrange the wirings in the resin substrate. Specifically, wirings that are extended from the semiconductor chip to upper package connection pads (surface substrate wirings) provided on the front surface of the substrate and wirings that are extended from the semiconductor chip to solder balls provided on the rear surface of the substrate coexist. Therefore, a substrate having multiple layers is required so as to avoid intersection of these wirings, which cannot be achieved by the technique of Document 1. Moreover, since a multilayer substrate generally requires high cost, it is desirable to avoid the use of the multilayer substrate if possible.

Moreover, for a manufacturer that stacks the upper and lower packages, special equipment is required when stacking is performed with respect to a semiconductor device employing a tape substrate as disclosed in Document 1. Therefore, it is more difficult to handle a product employing a tape substrate than a product employing a resin substrate as shown in FIG. 23.

In view of the aforementioned problems, a technique of solving the poor contact problem with solder balls during stacking, and simplifying the design of a substrate of a lower package, in a semiconductor package having a multilayer structure, will be hereinafter described.

A semiconductor device according to the present disclosure includes a substrate having a substrate wiring, a semiconductor chip provided on the substrate, a first electrical conductor electrically connecting the semiconductor chip and the substrate wiring, an electrically conductive pad provided on the substrate, and a wiring member electrically connected to the electrically conductive pad and serving as a wiring path different from the substrate wiring.

When such a semiconductor device is used as a lower package, and an upper package is stacked on the lower package to form a PoP semiconductor device, it is possible to prevent the poor contact problem with a solder ball due to warpage of the upper and lower packages, and facilitate the design of a substrate in the lower package, as described below.

In PoP semiconductor devices, it is necessary to form a first wiring path connecting a semiconductor chip of the lower package to a semiconductor chip of the upper package, and a second wiring path connecting the semiconductor chip of the lower package to a rear surface of the substrate of the lower package in a manner that allows the first and second wiring paths to coexist without intersecting each other. In the case of a PoP semiconductor device as described with reference to FIG. 23, these two wiring paths need to be formed using only wirings in the substrate of the lower package. As a result, it is necessary to use a substrate having multiple layers.

By contrast, in the case of the semiconductor device of the present disclosure, a wiring member provided on a substrate can be utilized to form a wiring path (particularly, a first wiring path connected to a semiconductor chip of the upper package) different from a substrate wiring. Therefore, the design of a substrate wiring formed on a substrate can be facilitated, so that a substrate including a smaller number of layers (or a single layer) than that of the conventional art can be employed. As a result, the cost, design period and the like of a substrate can be reduced.

Here, an increase in height of a semiconductor device due to the wiring member provided on the substrate is canceled by a reduction in the number of layers in the substrate. Therefore, an increase in height of the semiconductor device is prevented.

The semiconductor device of the present disclosure preferably further includes a tape substrate having a tape substrate wiring and an insulating layer sandwiching the tape substrate wiring and provided on the substrate and the semiconductor chip, and a second electrical conductor electrically conducting the tape substrate wiring and the substrate wiring. The wiring member is preferably the tape substrate wiring. The electrically conductive pad is preferably provided on the tape substrate and is electrically connected to the tape substrate wiring.

Also, in the semiconductor device of the present disclosure, the wiring member is preferably a metal fine wire.

As a part for achieving the wiring member, the tape substrate has an excellent effect of reducing a height of the semiconductor device (preventing an increase in the height). The cost of the metal fine wire is advantageously low.

Also, an elastic adhesive material is preferably provided between the substrate and the electrically conductive pad.

In PoP semiconductor devices, the substrates of the upper and lower packages tend to warp in opposite directions, depending on a change in temperature. Therefore, the poor contact problem with a solder ball occurs due to a change in distance between the upper and lower packages with solder balls being interposed therebetween, for example. However, in the case of a PoP semiconductor device including the semiconductor device of the present disclosure as the lower package, the electrically conductive pad on the substrate of the lower package and the substrate of the upper package are connected using solder balls, and the electrically conductive pad and the substrate are connected using an adhesive material. Therefore, even if warpage occurring in the substrate causes a variation in distance between the substrates of the upper and lower packages, the occurrence of poor contact of solder balls can be prevented by deformation of the adhesive material.

Also, the semiconductor chip is preferably fixed onto the substrate using a paste or a sealing resin.

The semiconductor chip can be mounted in this manner.

Also, the semiconductor device of the present disclosure preferably further includes an adhesive or an adhesive sheet attaching the substrate and the tape substrate, the adhesive or adhesive sheet being provided in at least one of a region between the semiconductor chip and the second electrical conductor and a region between the second electrical conductor and the elastic adhesive material.

In this case, the substrate and the tape substrate can be more reliably connected. In particular, by providing the adhesive or adhesive sheet in the vicinity of the second electrical conductor, the reliability of connection of the second electrical conductor can be improved.

Also, the first electrical conductor is preferably a bonding wire connecting the semiconductor chip and the substrate wiring. The semiconductor device preferably further includes a sealing resin sealing the semiconductor chip and the bonding wire.

Thus, in the semiconductor device of the present disclosure, wire bonding having general versatility can be used, which requires lower cost than that of flip chip. Also, warpage of the package can be corrected by using the same mold sealing resin material as that of the upper package.

Also, the semiconductor device of the present disclosure preferably further includes at least another semiconductor chip provided on the semiconductor chip, a bonding wire connecting the at least another semiconductor chip and the substrate wiring, and a sealing resin sealing the semiconductor chip, the at least another semiconductor chip and the bonding wire. The elastic adhesive material and the second electrical conductor are preferably set to have a height depending on the presence of the at least another semiconductor chip.

Thus, the semiconductor device of the present disclosure is applicable when a plurality of semiconductor chips stacked on top of one another is employed, so that specifications for many purposes can be supported.

Also, the semiconductor device of the present disclosure preferably further includes an adhesive or an adhesive sheet attaching the substrate and the tape substrate and provided in a region including a position of the second electrical conductor. The second electrical conductor is preferably provided on the tape substrate and is preferably convex toward the substrate, and preferably penetrates through the adhesive or the adhesive sheet to electrically connect to the substrate wiring.

In this case, the use of the convex second electrical conductor enables an improvement in connection accuracy between the second electrical conductor and the substrate wiring. Also, the adhesive or adhesive sheet more reliably connects the tape substrate and the substrate. The tape substrate and the substrate can be connected only by pressing, which is a simple step. Therefore, the manufacturing cost and the manufacturing time can be reduced.

Also, the semiconductor device of the present disclosure preferably further includes an adhesive or an adhesive sheet attaching the substrate and the tape substrate and provided in a region including a position of the second electrical conductor. The second electrical conductor is preferably provided on the substrate and is preferably convex toward the tape substrate, and preferably penetrates through the adhesive or the adhesive sheet to electrically connect to the tape substrate wiring.

Also in this case, the connection accuracy of the second electrical conductor and the substrate wiring can be improved, and the reliability and simplicity of connection of the tape substrate and the substrate can be improved. Moreover, the second electrical conductor is provided on the substrate having higher rigidity than that of the tape substrate, and a tip of the convex shape is pressed against and attached to the tape substrate, resulting in a semiconductor device that can be assembled more stably and accurately.

Also, the semiconductor device of the present disclosure preferably further includes at least one hole penetrating through a portion of the tape substrate closer to the semiconductor chip than the second electrical conductor. A sealing resin is preferably injected between the substrate and the tape substrate.

In this case, the semiconductor chip can be sealed with a resin. Moreover, when a package in which a semiconductor chip is sealed with a resin is used as the upper package of a PoP semiconductor device, the structure of the lower package is caused to be similar to the structure of the upper package, so that the substrates of the lower and upper warpages can warp in a similar manner (e.g., in the same direction).

Also, the semiconductor device of the present disclosure preferably further includes a plurality of holes penetrating through at least one of a portion of the tape substrate closer to the semiconductor chip than the adhesive or adhesive sheet and a portion of the tape substrate between the adhesive or adhesive sheet and the elastic adhesive material.

In this case, heat radiation from a space between the resin substrate and the tape substrate can be improved by circulating air through the holes provided in the tape substrate.

Also, the semiconductor device of the present disclosure preferably further includes a dummy wiring provided in the tape substrate, circumventing the tape wiring and extending from a region on the semiconductor chip to a peripheral portion of the tape substrate, and a heat conductor connecting an upper surface of the semiconductor chip and the dummy wiring.

In this case, a path is provided that allows heat to escape from the upper surface of the semiconductor chip to the outside of the semiconductor device through the heat conductor and the dummy wiring, resulting in an improvement in heat radiation.

Also, the electrically conductive pad is preferably provided on the second electrical conductor.

In this case, when the semiconductor device of the present disclosure is included as a lower package in a PoP semiconductor device, a current path from a semiconductor chip in the lower package to a semiconductor chip in the upper package can be shortened, resulting in a reduction in impedance.

Also, the elastic adhesive material and the second electrical conductor preferably have a thickness higher than an upper surface of the semiconductor chip.

In this case, the tape substrate can be caused to be flat. Therefore, the flexibility of a size, a position and the like of the electrical conductor for connecting the tape substrate and the upper package increases. Therefore, the number of signal connections between the upper and lower packages in a PoP semiconductor device can be increased.

Also, the tape substrate preferably further includes another tape wiring and another insulating layer to have a multilayer structure having two or more layers.

In this case, the flexibility of signal connection between the upper and lower packages in a PoP semiconductor device increases, so that the design of wirings can be facilitated.

Also, a package including a second substrate on which a second semiconductor chip is provided is preferably provided above the substrate, and the electrically conductive pad and the second semiconductor chip are preferably electrically connected.

A PoP semiconductor device including the semiconductor device of the present disclosure as a lower package solves the solder ball poor contact problem described above, and facilitates the design of the substrate of the lower package, for example.

To achieve the object, a first manufacture method of the semiconductor device of the present disclosure includes the steps of (a) providing a semiconductor chip on a substrate having a substrate wiring, and (b) providing a tape substrate having a tape wiring sandwiched by an insulating layer, on the substrate and the semiconductor chip. Step (a) includes electrically connecting the substrate wiring and the semiconductor chip via a first electrical conductor. Step (b) includes electrically connecting the substrate wiring and the tape wiring via a second electrical conductor, and attaching the tape substrate and the substrate using an adhesive material. An electrically conductive pad connected to the tape wiring is provided on a side opposite to the substrate of the tape wiring.

Also, a second manufacture method of the semiconductor device of the present disclosure includes the steps of providing a semiconductor chip on a substrate having a substrate wiring, and providing, on the substrate, an electrically conductive pad, and a wiring member electrically connected to the electrically conductive pad and serving as a wiring path different from the substrate wiring.

The semiconductor device of the present disclosure can be manufactured by the aforementioned semiconductor device manufacturing methods.

As described above, according to the technique of the present disclosure, the solder ball poor contact problem due to a difference in warpage between an upper package and a lower package stacked on top of one another in a PoP semiconductor device can be solved. Also, the design of the substrate wiring in the lower package can be facilitated, resulting in a reduction in substrate cost and a design period. Therefore, the technique of the present disclosure is particularly useful for semiconductor devices used in the field of electrical apparatuses, such as a mobile telephone, a digital still camera and the like, which require high cost, a long development period and the like.

### BRIEF DESCRIPTION OF THE DRAWINGS

FIG. 1A is a cross-sectional view of an example semiconductor device according to a first embodiment as viewed from a side thereof.

FIGS. 1B and 1C are cross-sectional views of an upper package and a lower package of the semiconductor device as viewed from a side thereof.

FIG. 2 is a plan view of a tape substrate of the example semiconductor device of the first embodiment as viewed from the top.

FIG. 3 is a plan view of an example resin substrate of the first embodiment as viewed from the top.

FIG. 4 is a cross-sectional view of an example semiconductor device according to a second embodiment as viewed from a side thereof.

FIG. 5 is a cross-sectional view of an example semiconductor device according to a third embodiment as viewed from a side thereof.

FIG. 6 is a cross-sectional view of an example semiconductor device according to a fourth embodiment as viewed from a side thereof.

FIG. 7 is a plan view of an example resin substrate of the fourth embodiment as viewed from the top.

FIG. 8 is a cross-sectional view of manufacture of an example lower package of the fourth embodiment.

FIG. 9 is a cross-sectional view of an example semiconductor device according to a fifth embodiment as viewed from a side thereof.

FIG. 10 is a cross-sectional view of manufacture of an example lower package of the fifth embodiment.

FIG. 11 is a cross-sectional view of an example semiconductor device according to a sixth embodiment as viewed from a side thereof.

FIG. 12 is a cross-sectional view of injection of a mold sealing resin in the example lower package of the sixth embodiment.

FIG. 13 is a plan view of an example tape substrate of the sixth embodiment as viewed from the top.

FIG. 14 is a cross-sectional view of an example semiconductor device according to a seventh embodiment as viewed from a side thereof.

FIG. 15 is a plan view of an example tape substrate of the seventh embodiment as viewed from the top.

FIG. 16 is a cross-sectional view of an example semiconductor device according to an eighth embodiment as viewed from a side thereof.

FIG. 17 is a plan view of an example tape substrate of the eighth embodiment as viewed from the top.

FIG. 18 is a cross-sectional view of an example semiconductor device according to a ninth embodiment as viewed from a side thereof.

FIG. 19 is a plan view of an example tape substrate of the ninth embodiment as viewed from the top.

FIG. 20 is a cross-sectional view of an example semiconductor device according to a tenth embodiment as viewed from a side thereof.

FIG. 21 is a cross-sectional view of an example semiconductor device according to an eleventh embodiment as viewed from a side thereof.

FIG. 22 is a plan view of an example tape substrate of the eleventh embodiment as viewed from the top.

FIG. 23 is a cross-sectional view of a conventional semiconductor device as viewed from a side thereof.

FIG. 24A is a cross-sectional view of an example semiconductor device according to a twelfth embodiment as viewed from a side thereof.

FIGS. 24B and 24C are cross-sectional views of an upper package and a lower package of the semiconductor device as viewed from a side thereof.

### DETAILED DESCRIPTION

Hereinafter, embodiments of the present disclosure will be described with reference to the accompanying drawings. Note that like parts are indicated with like reference symbols and will not be repeatedly described in detail. Also, thicknesses, lengths and the like shown in the figures are not necessarily equal to actual ones. Connection electrodes of a semiconductor chip, connection terminals of a substrate, wiring patterns, via holes and the like may not be shown or the numbers and shapes thereof may be altered for the sake of convenience in some cases.

### First Embodiment

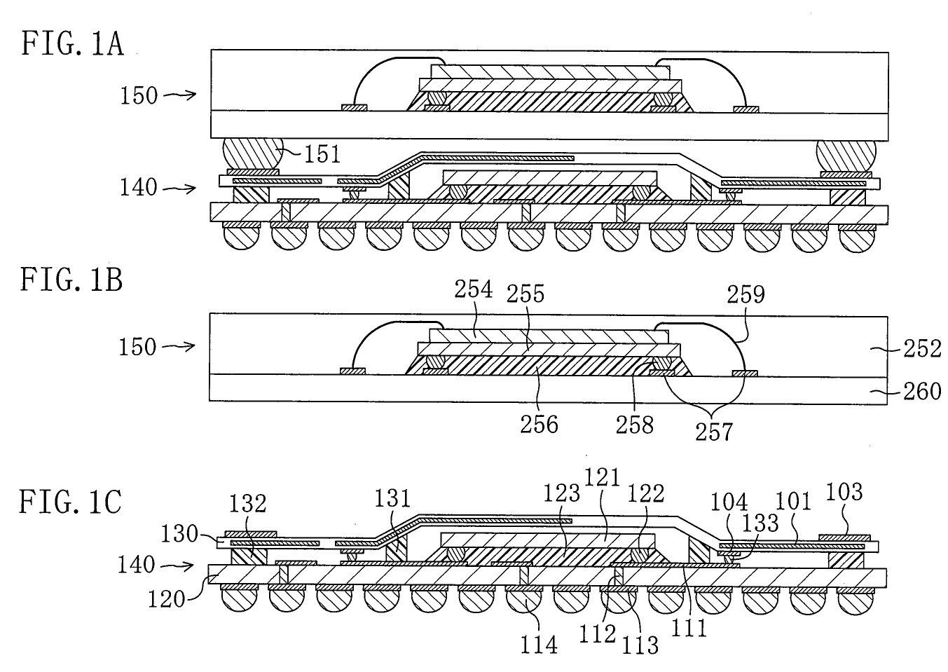

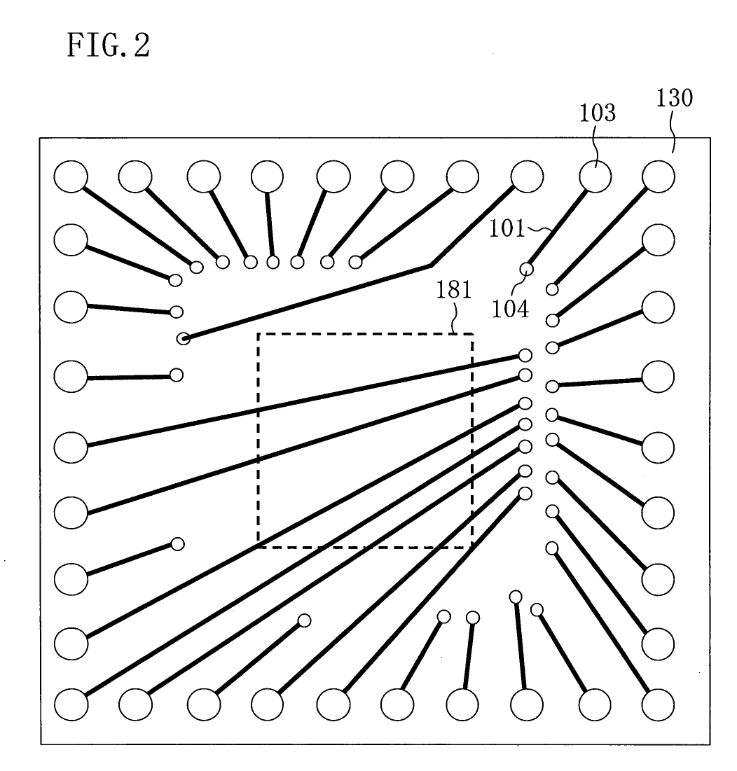

An example semiconductor device according to a first embodiment will be described with reference to FIGS. 1A to 1C, 2 and 3.

FIG. 1A is a cross-sectional view of a PoP semiconductor device in which an upper package 150 is stacked on a lower package 140 with solder balls 151 being interposed therebetween. FIG. 1B is a cross-sectional view of the upper package 150. FIG. 1C is a cross-sectional view of the lower package 140.

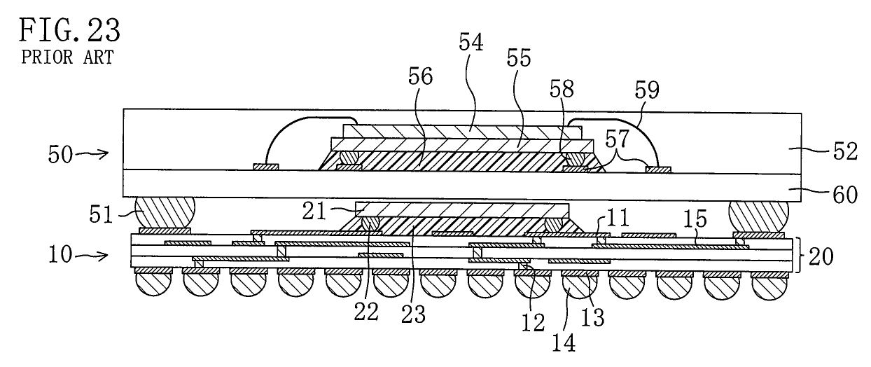

The upper package 150 of FIG. 1B is similar to that of the conventional PoP semiconductor device of FIG. 23. Specifically, the upper package 150 has a structure in which a stack of semiconductor chips 254 and 255 is fixed to a resin substrate 260 using an adhesive sheet 256, and is sealed with a mold sealing resin 252. Here, substrate wirings 257 are provided on the resin substrate 260. Some of the substrate wirings 257 are electrically connected to the semiconductor chip 254 via bonding wires 259, while the other substrate wirings 257 are electrically connected to the semiconductor chip 255 via gold bumps 258. Also, electrical connection paths from the substrate wirings 257 to the resin substrate 260 are provided by means of via holes or the like, though not particularly shown. Note that the upper package 150 thus configured is an exemplary product manufactured by a manufacturer. In this embodiment, a method for mounting the upper package 150 to a semiconductor chip is not particularly limited, for example.

Next, the lower package 140 of FIG. 1C includes a resin substrate 120. Front-surface substrate wirings 111 are provided on one surface (hereinafter referre to as a front surface) of the resin substrate 120, while rear-surface substrate wirings 113 are provided on the other surface (hereinafter referred to as a rear surface) thereof. The front-surface substrate wirings 111 and the rear-surface substrate wirings 113 are connected via via holes 112 penetrating through the resin substrate 120.

A semiconductor chip 121 is mounted on the front surface of the resin substrate 120. The semiconductor chip 121 is fixed onto the resin substrate 120 using an adhesive sheet 123, and is electrically connected via gold bumps 122 to the front-surface substrate wirings 111.

A tape substrate 130 is mounted above the resin substrate 120 and the semiconductor chip 121. The tape substrate 130 has a structure in which tape substrate wirings 101 made of copper are sandwiched by a polyimide resin layer (insulating layer) 102. Gold-plated rear surface copper pads 104 are provided on a surface (hereinafter referred to as a rear surface) closer to the resin substrate 120 of the tape substrate 130. The rear surface copper pads 104 are electrically connected to the front-surface substrate wirings 111 via solder balls 133. Moreover, front surface copper pads 103 for providing electrical connection to the upper package 150 are provided on a surface (hereinafter referred to as a front surface) opposite to the resin substrate 120 of the tape substrate 130. The front surface copper pads 103 are plated with gold and are connected to the tape substrate wirings 101.

In order to mount the tape substrate 130, an adhesive sheet 131 and an elastic adhesive sheet 132 are used in addition to the solder balls 133. In this embodiment, the adhesive sheet 131 is provided between the semiconductor chip 121 and the solder balls 133 and closer to the solder balls 133, attaching the resin substrate 120 and the tape substrate 130. The elastic adhesive sheet 132 is provided on the rear surface of the tape substrate 130 and at positions corresponding to the front surface copper pads 103.

FIG. 2 is a plan view of the tape substrate 130. In FIG. 2, a position at which the semiconductor chip 121 is mounted is shown as a frame 181. The front surface copper pads 103 are provided on a peripheral portion of the tape substrate 130. The rear surface copper pads 104 are provided farther inside than the peripheral portion of the tape substrate 130 and around the frame 181. The front surface copper pads 103 are connected to the respective rear surface copper pads 104 via the respective tape substrate wirings 101.

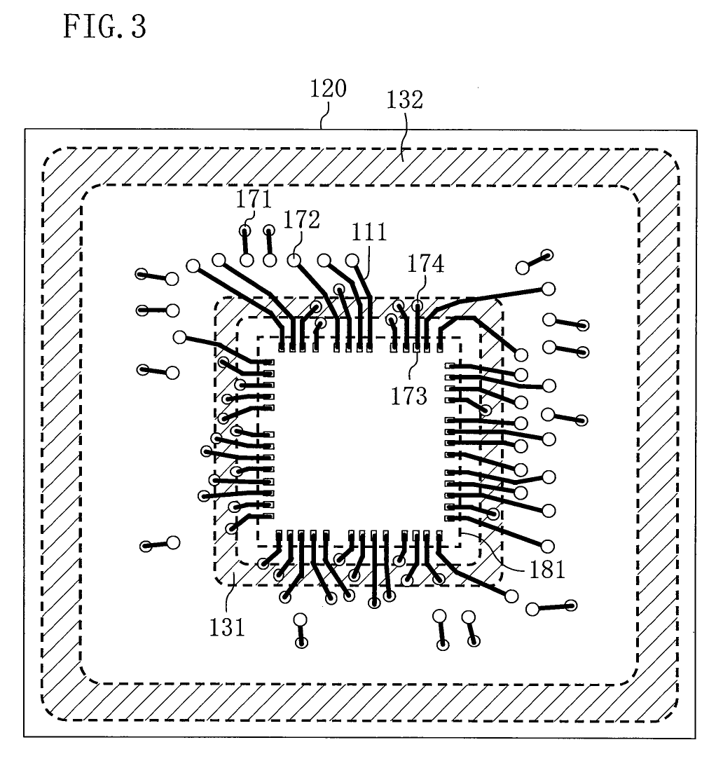

FIG. 3 is a plan view of the resin substrate 120. In FIG. 3, a position at which the semiconductor chip 121 is provided is indicated as a frame 181.

Copper pads 173 are provided on a peripheral portion of the frame 181. The gold bumps 122 for providing connection to the semiconductor chip 121 are provided on the copper pads 173. Gold-plated copper pads 172 are provided outside the frame 181. The solder balls 133 for providing connection to the tape substrate 130 are provided on the gold-plated copper pads 172. Therefore, a size of the copper pad 172 is determined, depending on accuracy with which the solder ball 133 is mounted on the copper pad 172. If the positioning accuracy is poor, a larger size is required. Moreover, copper pads 171 connected to the via holes 112 are provided. The copper pads 171 are connected to the respective copper pads 172 via the respective front-surface substrate wirings 111, and the copper pads 172 are connected to the respective copper pads 173 via the respective front-surface substrate wirings 111.

Note that positions of the elastic adhesive sheet 132 provided on the peripheral portion of the resin substrate 120 and the adhesive sheet 131 provided outside the frame 181 are also shown. Although it is here assumed that the adhesive sheet 131 is provided in a region between the copper pads 172 contacting the solder ball 133 and the frame 181, the adhesive sheet 131 may be instead provided outside the copper pad 172.

The lower package 140 of this embodiment includes the tape substrate 130 having a function of connecting to the upper package 150 in addition to a configuration in which a semiconductor chip is mounted on a substrate.

When the lower package 140 that is a semiconductor device having such a structure is manufactured, the semiconductor chip 121 is mounted at the position of the frame 181 on the resin substrate 120 of FIG. 3, and thereafter, the elastic adhesive sheet 132 is attached onto the resin substrate 120.

Next, as also shown in FIG. 1C, the tape substrate 130 is arranged on the resin substrate 120 with reference to the connection of the solder balls 133, and is temporarily connected using the elastic adhesive sheet 132. Here, conductive pads 103 are typically provided on the tape substrate 130 before the connection.

Thereafter, the tape substrate 130 is heated to a temperature of 220° C. to 250° C. that is the melting point of solder while being pressed from the above, whereby the tape substrate 130 is finally attached to the resin substrate 120.

Note that, in this embodiment, the adhesive sheet 131 of FIG. 3 is used to improve the reliability of connection. The adhesive sheet 131 allows the stability of temporary connection and the enforcement of final connection by melting solder.

The upper package 150 and the lower package 140 as described above are separately assembled, and thereafter, the upper package 150 is stacked on the lower package 140 by a reflow process or the like, resulting in the PoP semiconductor device of FIG. 1A.

In this case, the solder balls 151 are provided on the front surface copper pads 103 on the tape substrate 130 in the lower package 140. The lower package 140 and the upper package 150 are electrically connected via the solder balls 151. The electrical connection will be hereinafter described.

As shown in FIGS. 2 and 3, wiring paths (and the tape substrate wirings 101 as a part thereof) connected from the semiconductor chip 121 mounted on the lower package 140 to the upper package 150 are spread from one side of the semiconductor chip 121 toward the four sides of the upper package 150, extending from end to end of the package.

Also, in the PoP semiconductor device, it is necessary to provide first wiring paths for electrically connecting the semiconductor chip of the lower package to the semiconductor chip of the upper package, and second wiring paths for electrically connecting the semiconductor chip of the lower package to the solder balls and the like on the substrate rear surface of the lower package.

In the case of the conventional PoP semiconductor device of FIG. 23, the first wiring paths are extended from the semiconductor chip 21 via the surface substrate wirings 11, the via holes 12, the interlayer wirings 15 and the like to the solder balls 51 of the upper package 50. The second wiring paths are extended from the semiconductor chip 21 via the surface substrate wirings 11, the via holes 12, the interlayer wirings 15 and the rear surface substrate 13 to the solder balls 14. Thus, only wirings within the resin substrate 20 are used to provide the first and second wiring paths in a manner that allows them to coexist without intersecting each other.

Therefore, in the PoP semiconductor device of FIG. 23, the resin substrate 20 needs to include a larger number of layers. For example, two layers are not sufficient to extend wirings, and four layers are required (in some cases, even four layers are not sufficient, and six layers are required).

By contrast, in the case of the PoP semiconductor device of FIG. 1A, the tape substrate wirings 101 in the tape substrate 130 provided on the resin substrate 120 are utilized to provide the first wiring path connecting the semiconductor chip 121 to the upper package 150. Therefore, the second wiring paths connecting the semiconductor chip 121 to the solder balls 114 on the rear surface of the resin substrate 120 can be separated from the first wiring paths.

Therefore, as shown in FIG. 2, the tape substrate wirings 101 can be caused to pass over a region (the frame 181) in which the semiconductor chip 121 is provided, so that the tape substrate wirings 101 can have a minimum distance.

Also, for the resin substrate 120, wiring paths can be caused to be simple. Therefore, the design of wirings is facilitated, so that a substrate having a smaller number of layers and requiring lower cost can be employed. Therefore, an increase in a height of the lower package 140 caused by providing the tape substrate 130 can be canceled by a reduction in the number of layers of the resin substrate 120. In other words, an increase in the height of the lower package 140 can be prevented.

Moreover, since the tape substrate 130 is thin and can be easily deformed, the tape substrate 130 can be connected to the solder balls 133, the solder balls 151, the elastic adhesive sheet 132 and the like at positions lower than the upper surface of the semiconductor chip 121. Therefore, an increase in a height of a PoP semiconductor device in which upper and lower packages are stacked can be prevented.

Next, warpage of the upper package 150 and the lower package 140 will be described.

When the lower package 140 and the upper package 150 are heated to high temperature so as to connect them, the upper package 150 warps into a convex shape (a portion in the vicinity of a middle of the resin substrate 260 protrudes toward the semiconductor chip 255). At the same time, the lower package 140 warps into a concave shape (a portion in the vicinity of a middle of the resin substrate 120 protrudes toward a side opposite to the semiconductor chip 121).

After the connection of the packages, when the temperature is returned to room temperature, the upper package 150 warps into a concave shape, while the lower package 140 warps into a convex shape. Thus, the upper package 150 and the lower package 140 tend to warp in opposite directions, and each of them tends to warp in opposite directions at different temperatures. Therefore, a distance between the upper and lower packages varies depending on the position of a solder ball connecting the upper and lower packages, which may lead to the occurrence of poor connection at the solder ball.

However, in the case of the PoP semiconductor device of this embodiment, the solder balls 151 connecting the upper and lower packages connect the front surface copper pads 103 provided on the tape substrate 130 that can be easily deformed and the upper package 150. Moreover, the tape substrate 130 is not fixed between the fixation positions of the solder balls 133 and the positions of the elastic adhesive sheet 132, so that the solder balls 151 can freely move around the solder balls 133 within a range that allows the elastic adhesive sheet 132 and the tape substrate 130 to deform.

Therefore, even if the upper and lower packages warp in opposite directions, the warpage can be compensated for by the deformation of the tape substrate 130, so that poor connection of the solder balls 151 can be reduced.

Note that, in this embodiment and the following second to twelfth embodiments, materials for parts are not particularly limited and a method for mounting a semiconductor chip is also not limited to those described herein.

### Second Embodiment

Hereinafter, a second embodiment will be described. In this embodiment, wire bonding is used instead of flip chip as a method for mounting a semiconductor chip on a lower package.

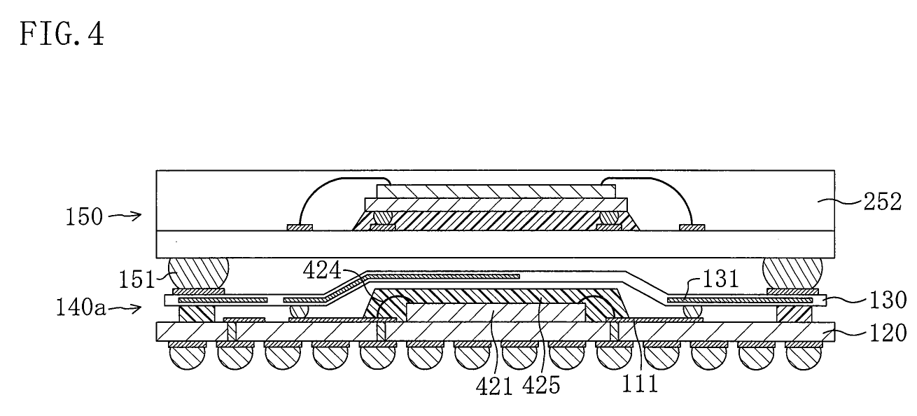

FIG. 4 is a cross-sectional view of an example PoP semiconductor device according to this embodiment.

The example semiconductor device has a structure in which an upper package 150 is stacked on a lower package 140a with solder balls 151 being interposed therebetween, which is similar to that of the example semiconductor device of the first embodiment of FIG. 1A. Here, the upper package 150 has the same structure as that of the first embodiment. The lower package 140a is different from that of the lower package 140 of the first embodiment in a method for mounting a semiconductor chip.

In the case of the first embodiment, as shown in FIG. 1C, a semiconductor chip is mounted by flip chip. Specifically, the semiconductor chip 121 is fixed onto the resin substrate 120 using the adhesive sheet 123, and the semiconductor chip 121 and the front-surface substrate wirings 111 on the resin substrate 120 are electrically connected via the gold bumps 122.

By contrast, in the case of the example semiconductor device of this embodiment of FIG. 4, a semiconductor chip is mounted by wire bonding. Specifically, a semiconductor chip 421 is mounted on a resin substrate 120, electrode pads (not shown) on an upper surface of the semiconductor chip 421 and front-surface substrate wirings 111 on the resin substrate 120 are connected by bonding wires 424, and the semiconductor chip 421 and the bonding wires 424 are sealed with a mold sealing resin 425.

The semiconductor device of this embodiment has the same structure as that of the semiconductor device of the first embodiment, except for the aforementioned parts, and has an effect similar to that of the semiconductor device of the first embodiment.

The cost of wire bonding is lower than that of flip chip. Wire bonding is particularly useful when a semiconductor chip is smaller than in the first embodiment. Also, when the mold sealing resin 425 is made of the same material as that of the mold sealing resin 252 used in the upper package 150, warpage of the upper package 150 and the lower package 140a can be corrected so that the upper package 150 and the lower package 140a warp in the same direction.

Note that when an upper portion of the mold sealing resin 425 has a corner portion (particularly, an acute angle), the tape substrate wirings 101 in the tape substrate 130 are likely to be cut. Therefore, after the semiconductor chip 421 is sealed with the mold sealing resin 425 and before the tape substrate 130 is mounted, the acute angle portion is polished into a round shape, thereby preventing the tape substrate wirings 101 from being cut.

### Third Embodiment

Hereinafter, a third embodiment will be described. In this embodiment, a plurality of semiconductor chips are mounted to a lower package.

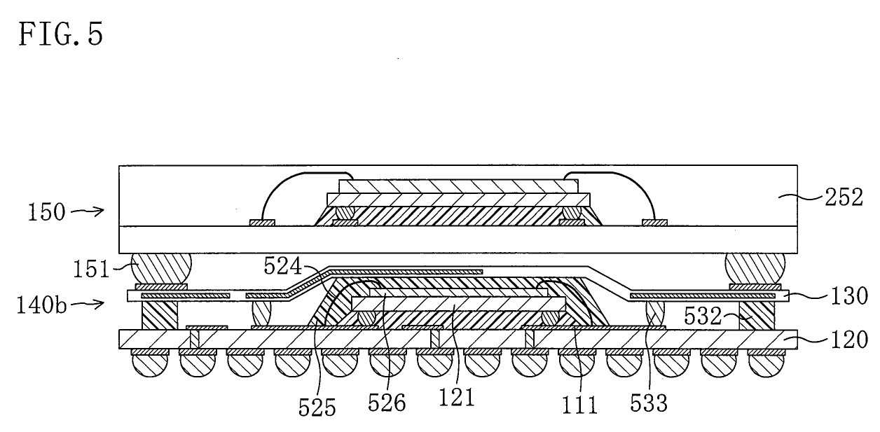

FIG. 5 is a cross-sectional view of an example PoP semiconductor device of this embodiment.

The example semiconductor device of this embodiment has a structure in which an upper package 150 is stacked on a lower package 140b with solder balls 151 being interposed therebetween, which is similar to that of the semiconductor device of the first embodiment of FIG. 1A. Here, the upper package 150 has the same structure as that of the first embodiment. The lower package 140b is different from the lower package 140 of the first embodiment in a semiconductor chip.

In the first embodiment, as shown in FIG. 1C, the semiconductor chip 121 is mounted by flip chip. By contrast, in the case of the lower package 140b of this embodiment of FIG. 5, another semiconductor chip 526 is stacked on the semiconductor chip 121 mounted by flip chip. The semiconductor chip 526 is electrically connected to front-surface substrate wirings 111 on a resin substrate 120 via bonding wires 524. The semiconductor chip 121, the semiconductor chip 526 and the bonding wires 524 are sealed with a mold sealing resin 425.

The semiconductor device of this embodiment has the same structure as that of the semiconductor device of the first embodiment, except for the aforementioned parts, and when a plurality of semiconductor chips are stacked, has an effect similar to that of the semiconductor device of the first embodiment.

Note that, as compared to the first and second embodiments, semiconductor chips are stacked, so that a height required for mounting the semiconductor chips is large. Therefore, a thickness of an elastic adhesive sheet 532 and a size of a solder ball 533 are caused to be larger than those of the first and second embodiments.

Also, as is similar to the second embodiment, a corner of an upper portion of a mold sealing resin 525 is rounded, thereby making it possible to prevent tape substrate wirings 101 from being cut. Moreover, by using a mold sealing resin 525 that is the same as the mold sealing resin 252 used in the upper package 150, warpage of the upper and lower packages can be corrected.

### Fourth Embodiment

Hereinafter, a fourth embodiment will be described. This embodiment is obtained by making changes to the solder ball 133 and the adhesive sheet 131 of the lower package of the first embodiment.

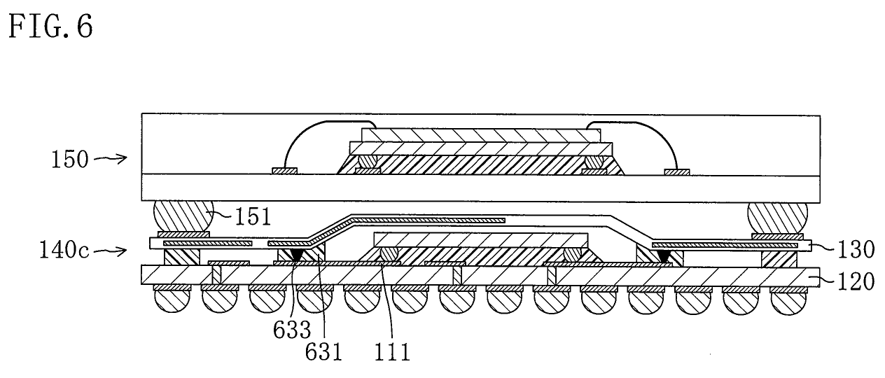

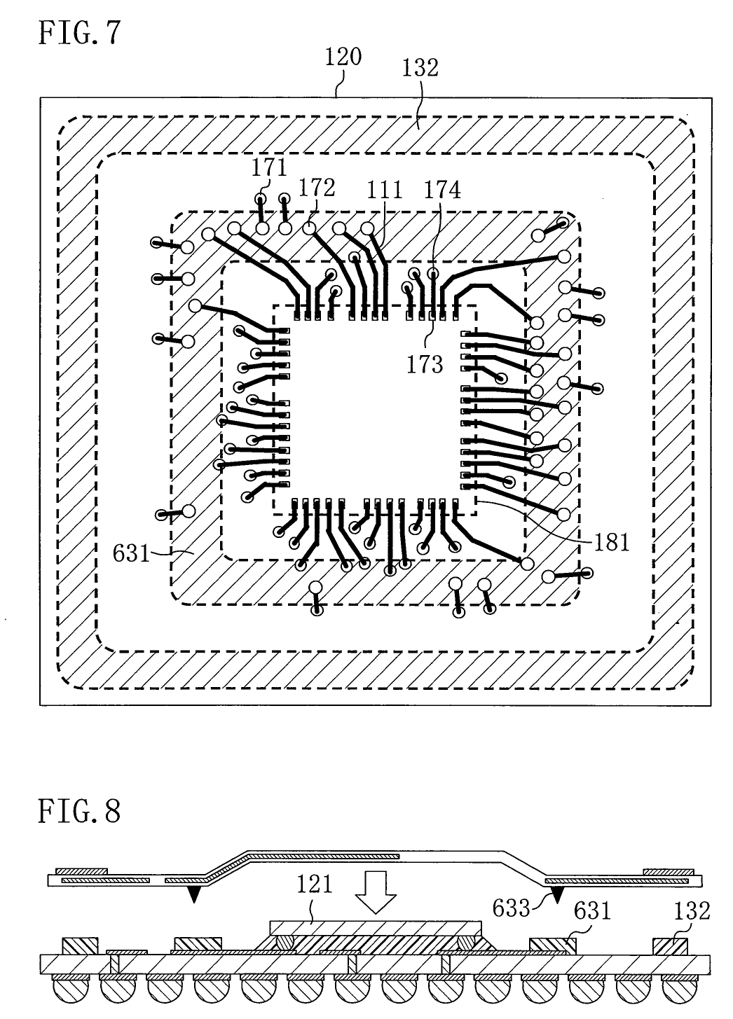

FIG. 6 is a cross-sectional view of an example PoP semiconductor device of this embodiment. FIG. 7 is a plan view of a resin substrate 120 of a lower package 140c.

The example semiconductor device of this embodiment has a structure in which an upper package 150 is stacked on the lower package 140c with solder balls 151 being interposed therebetween, which is similar to the semiconductor device of the first embodiment of FIG. 1A. Here, the upper package 150 has the same structure as that of the first embodiment. The lower package 140c is different from the lower package 140 of the first embodiment in a method for mounting the tape substrate 130 onto the resin substrate 120.

In the first embodiment, as shown in FIG. 1C, the tape substrate 130 is mounted on the resin substrate 120 using the solder balls 133 provided between the front-surface substrate wirings 111 and the rear surface copper pads 104.

By contrast, in this embodiment, instead of the solder balls 133, gold bumps 633 connected to tape substrate wirings 101 are provided on a rear surface of a tape substrate 130. The gold bumps 633 are connected to front-surface substrate wirings 111 while being buried in an adhesive sheet 631, penetrating therethrough.

As shown in FIG. 7, an adhesive sheet 631 is provided in a region including gold-plated copper pads 172 in a resin substrate 120. Here, gold bumps 633 are provided on the copper pads 172 and are buried in the adhesive sheet 631.

FIG. 8 shows a method for mounting a tape substrate 130 using the gold bumps 633. Initially, the adhesive sheet 631 and an elastic adhesive sheet 132 are attached to predetermined positions of the resin substrate 120 on which the semiconductor chip 121 and the like have been mounted. Also, on a rear surface of the tape substrate 130, the gold bumps 633 electrically connected to the tape substrate wirings 101 are shaped into stud bumps that are convex toward the resin substrate 120.

Thereafter, the tape substrate 130 is pressed against the resin substrate 120 while the gold bumps 633 are heated, so that the gold bumps 633 penetrates through the adhesive sheet 631 to connect to the front-surface substrate wirings 111 on the resin substrate 120.

According to the semiconductor device of this embodiment, in addition to an effect similar to that of the first embodiment, a size of the gold bump 633 can be caused to be smaller than that of the solder ball 133 of the first embodiment, so that it is easier to extend a wiring on the resin substrate 120. Also, in order to connect the tape substrate 130 and the resin substrate 120, it is easier to attach them by pressing using the gold bumps 633 than using solder balls having a size of, for example, about 200 μm. Therefore, the assembly step can be facilitated.

### Fifth Embodiment

Hereinafter, a fifth embodiment will be described. This embodiment is obtained by making changes to the gold bump 633, the adhesive sheet 631 and the elastic adhesive sheet 132 of the lower package in the fourth embodiment.

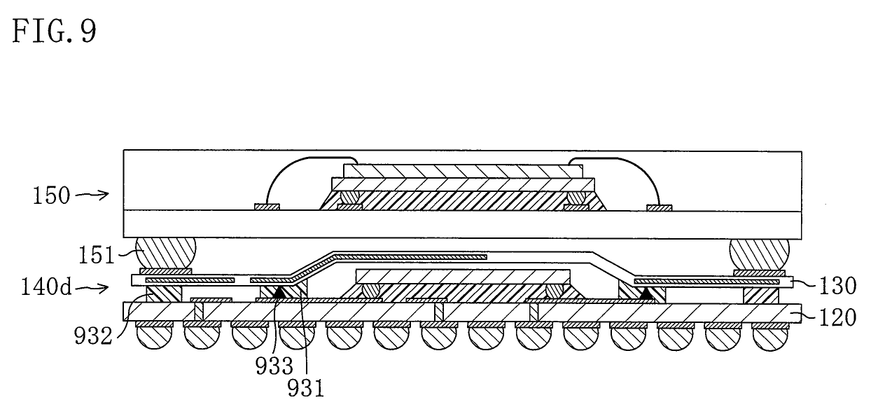

FIG. 9 is a cross-sectional view of an example PoP semiconductor device of this embodiment.

The example semiconductor device of this embodiment of FIG. 9 has a PoP structure in which an upper package 150 is stacked on a lower package 140d with solder balls 151 being interposed therebetween. In the lower package 140d, a tape substrate 130 is mounted on a resin substrate 120 with gold bumps 933 being interposed therebetween. This is similar to that of the semiconductor device of the fourth embodiment of FIG. 6. Note that the gold bumps 933 have a vertical orientation reverse to that of the gold bumps 633 in the semiconductor device of FIG. 6.

Specifically, in the semiconductor device of FIG. 6, the gold bumps 633 that are convex toward the resin substrate 120 are provided on the rear surface of the tape substrate 130. The gold bumps 633 penetrate through the adhesive sheet 631 to connect to the front-surface substrate wirings 111 on the resin substrate 120. By contrast, in the case of the semiconductor device of this embodiment, as shown in FIG. 9, the gold bumps 933 are provided on the front-surface substrate wirings 111 of the resin substrate 120. The gold bumps 933 are convex toward the tape substrate 130. The gold bumps 933 are buried therein the tape substrate 130, penetrating through an adhesive sheet 931, to connect to the tape substrate wirings 101.

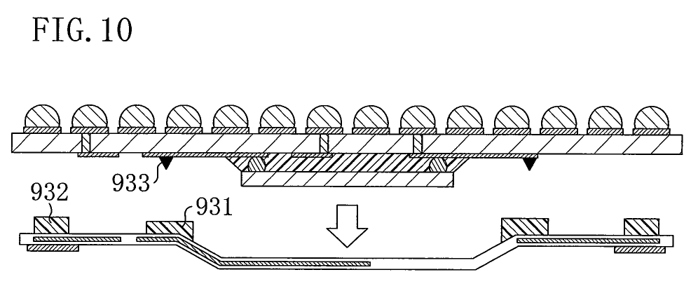

FIG. 10 shows a method for connecting the resin substrate 120 and the tape substrate 130 in this embodiment. Initially, as is converse to the fourth embodiment of FIG. 8, the adhesive sheet 931 and an elastic adhesive sheet 932 are attached to predetermined positions of a rear surface (facing upward in FIG. 10) of the tape substrate 130. Also, the gold bumps (stud bumps) 933 that are convex toward the tape substrate 130 are provided on the front-surface substrate wirings 111 of the resin substrate 120. Thereafter, by pressing the resin substrate 120 against the tape substrate 130, the gold bumps 933 penetrate through the adhesive sheet 931 to electrically connect to the tape substrate wirings 101 of the tape substrate 130. This step is also performed in a vertical direction reverse to that of the fourth embodiment (the resin substrate 120 is vertically inverted).

In this case, in addition to an effect similar to that of the fourth embodiment, the gold bumps 933 are provided on the resin substrate 120 that has greater rigidity than that of the tape substrate 130, so that the connection becomes more stable and accurate.

### Sixth Embodiment

Hereinafter, a sixth embodiment will be described. In this embodiment, through holes are provided in a tape substrate of a lower package, and a mold resin is injected thereinto, covering a semiconductor chip.

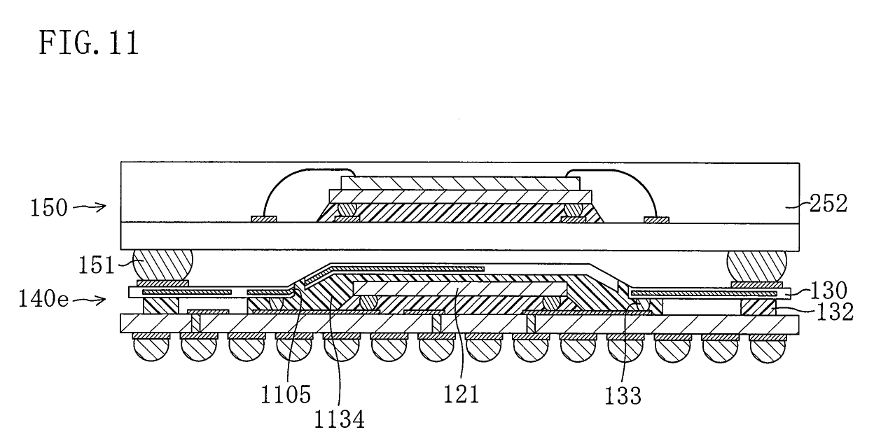

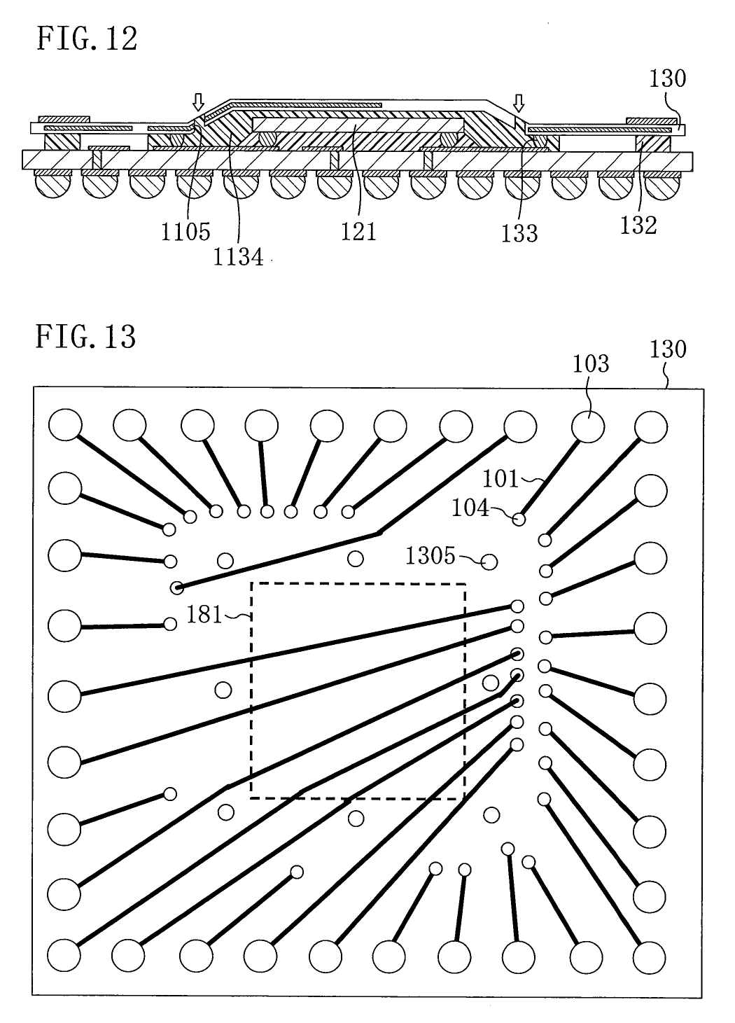

FIG. 11 is a cross-sectional view of an example PoP semiconductor device of this embodiment.

The example semiconductor device of this embodiment has a structure in which an upper package 150 is stacked on a lower package 140e with solder balls 151 being interposed therebetween, which is similar to the semiconductor device of the first embodiment of FIG. 1A. The upper package 150 has the same structure as that of the first embodiment.

The lower package 140e of this embodiment includes, in addition to the parts of the lower package 140 of the first embodiment of FIG. 1C, a mold sealing resin 1134 that seals the semiconductor chip 121 between the resin substrate 120 and the tape substrate 130. Also, in the example of FIG. 11, the adhesive sheet 131 connecting the resin substrate 120 and the tape substrate 130 is not provided.

FIG. 13 is a plan view of the resin substrate 120. As shown in FIG. 13, in the tape substrate 130, through holes 1105 for injecting the mold sealing resin 1134 are provided at positions closer to the semiconductor chip 121 than the rear surface copper pads 104 on which the solder balls 133 are provided. Also, FIG. 12 shows how the mold sealing resin 1134 is injected through the through holes 1105 into a space between the tape substrate 130 and the resin substrate 120.

Note that when the mold sealing resin 1134 is injected, it is necessary to control the mold sealing resin 1134 so that it does not spread to reach a vicinity of the elastic adhesive sheet 132. To achieve this, it is preferable to provide a component (breakwater, so to speak) for limiting a range within which the mold sealing resin 1134 spreads. For example, by providing the adhesive sheet 131 of FIG. 3 or the adhesive sheet 631 of FIG. 7, it is possible to prevent the mold sealing resin 1134 from spreading to the outside of these adhesive sheets.

Also, in order to prevent a void from occurring in the injected mold sealing resin 1134, the through holes 1105 need to be optimally arranged, taking into consideration a hole for injecting the resin and a hole for removing air.

The semiconductor device of this embodiment employs the mold sealing resin 1134 made of the same material as that of the mold sealing resin 252 of the upper package 150, thereby making it possible to correct warpage of the upper and lower packages so that the upper and lower packages warp in a similar manner (in the same direction, etc.), in addition to an effect similar to that of the first embodiment.

### Seventh Embodiment

Hereinafter, a seventh embodiment will be described. In this embodiment, through holes for passage of air to a tape substrate of a lower package to enhance heat radiation are provided.

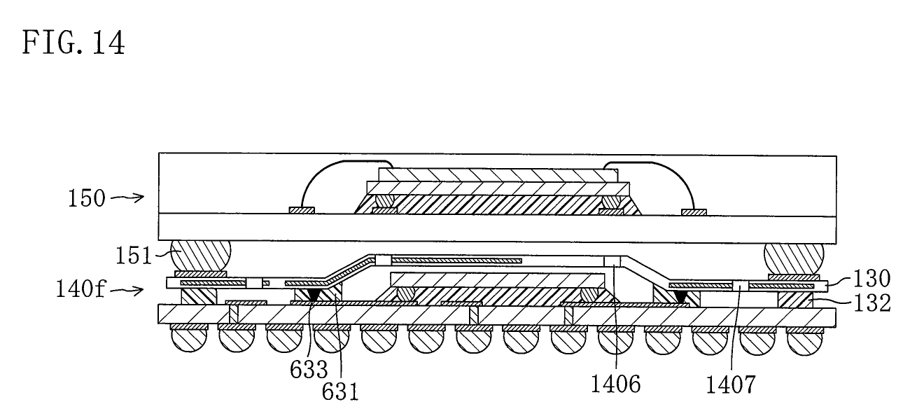

FIG. 14 is a cross-sectional view of an example PoP semiconductor device of this embodiment.

The example semiconductor device of this embodiment has a structure in which an upper package 150 is stacked on a lower package 140f with solder balls 151 being interposed therebetween, which is similar to the semiconductor device of the first embodiment of FIG. 1A.

The lower package 140f has a structure in which gold bumps 633 provided on the tape substrate 130 penetrate through an adhesive sheet 631 to connect to a resin substrate 120, which is similar to that of the lower package 140c of the fourth embodiment shown in FIG. 6.

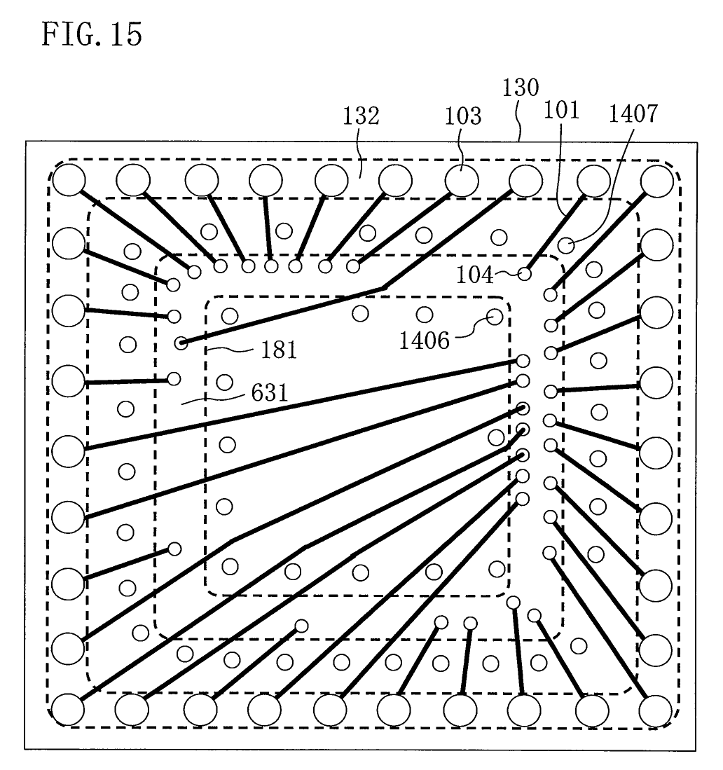

Moreover, in the tape substrate 130 of the lower package 140f, through holes 1406 are provided in a region closer to a semiconductor chip 121 than the adhesive sheet 631, while through holes 1407 are provided in a region between the adhesive sheet 631 and an elastic adhesive sheet 132. This can also be seen from FIG. 15 that is a plan view of the tape substrate 130.

In the semiconductor device of this embodiment, the through holes 1406 and 1407 allow enhancement of heat radiation of the lower package 140f.

Specifically, if the through holes 1406 are not provided in a space between the tape substrate 130 and the resin substrate 120 and farther inside than the adhesive sheet 631, the space is hermetically enclosed and air does not pass therethrough, so that it is difficult for heat generated in the semiconductor chip 121 to escape to the outside. However, in the semiconductor device of this embodiment, the through holes 1406 allow air to circulate, so that heat can be caused to easily escape to the outside.

Similarly, the through holes 1407 facilitate heat radiation in a region between the adhesive sheet 631 and the elastic adhesive sheet 132, as compared to when the through holes 1407 are not provided.

### Eighth Embodiment

Hereinafter, an eighth embodiment will be described. In this embodiment, a heat conductor is provided between a semiconductor chip and a tape substrate of a lower package, and dummy wirings for heat radiation are provided in the tape substrate.

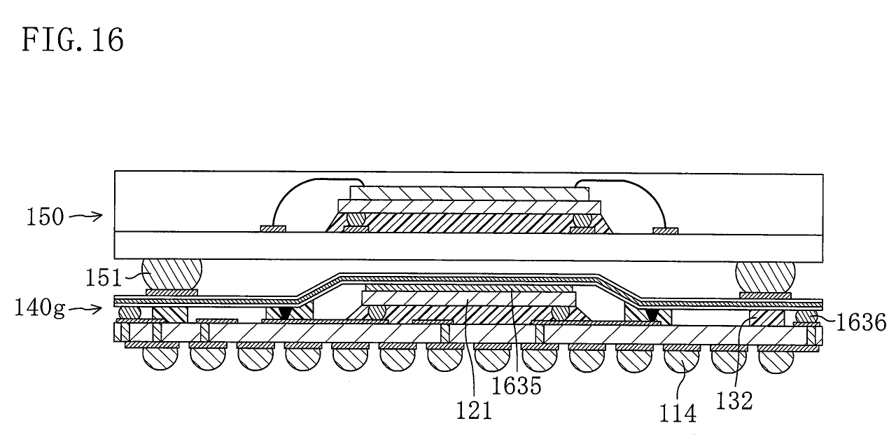

FIG. 16 is a cross-sectional view of an example PoP semiconductor device of this embodiment.

The example semiconductor device of this embodiment has a structure in which an upper package 150 is stacked on a lower package 140g with solder balls 151 being interposed therebetween, which is similar to the semiconductor device of the first embodiment of FIG. 1A.

The lower package 140g has a structure in which gold bumps 633 provided on a tape substrate 130 penetrate an adhesive sheet 631 to connect to a resin substrate 120, which is similar to the lower package 140c of the fourth embodiment of FIG. 6.

Moreover, the lower package 140g includes a heat conductor 1635 which is interposed between a semiconductor chip 121 and the tape substrate 130 and through which heat is conducted from the semiconductor chip 121 to the tape substrate 130, and a heat conductor 1636 which is interposed between the tape substrate 130 and the resin substrate 120 and outside the elastic adhesive sheet 132 and through which heat is conducted from the tape substrate 130 to the resin substrate 120.

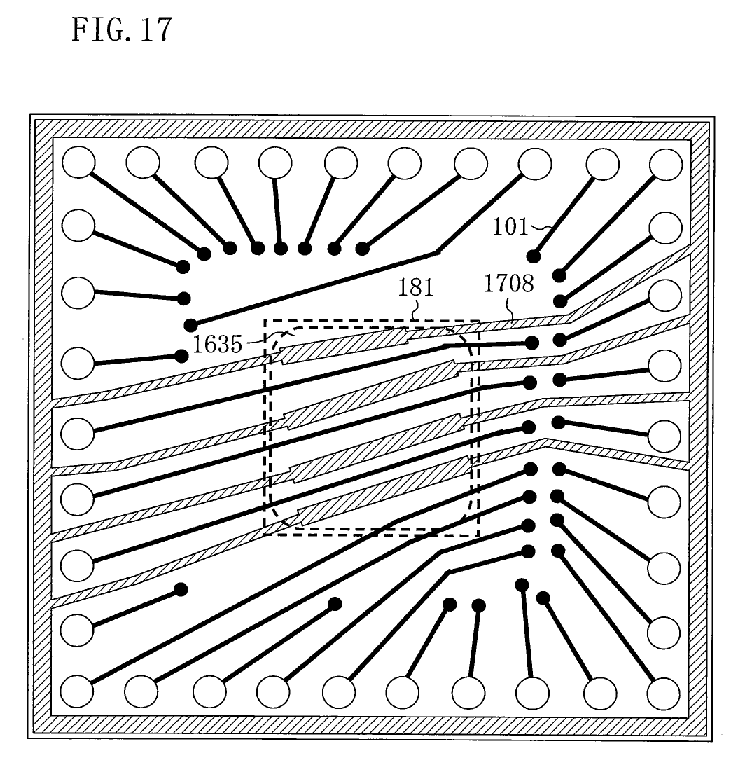

Also, as shown in FIG. 17 that is a plan view of the tape substrate 130, dummy wirings 1708 that are extended over the heat conductor 1635 to reach a peripheral portion of the tape substrate 130 are provided while circumventing tape substrate wirings 101. The dummy wirings 1708, which are sandwiched by an insulating layer as are similar to the tape substrate wirings 101, have a function of transferring heat generated from the semiconductor chip 121 (provided at a position indicated as a frame 181) to the peripheral portion of the tape substrate 130. Thereafter, heat that has reached the peripheral portion of the tape substrate 130 is radiated by air circulation or the like, or is transferred through the heat conductor 1636 of FIG. 16 to the resin substrate 120, and is then radiated through solder balls 114 to, for example, a mount substrate on which a semiconductor device is mounted.

In PoP semiconductor devices, a semiconductor chip (here, the semiconductor chip 121) interposed between the upper and lower packages generally has poor heat radiation. Therefore, it is important to improve heat radiation. In this embodiment, the heat conductors 1635 and 1636 and the dummy wirings 1708 work effectively so as to improve heat radiation.

### Ninth Embodiment

Hereinafter, a ninth embodiment will be described. In this embodiment, a portion of solder balls connecting upper and lower packages is provided closer to a center of a semiconductor device, so that wirings between the upper and lower packages are shortened, resulting in lower impedance.

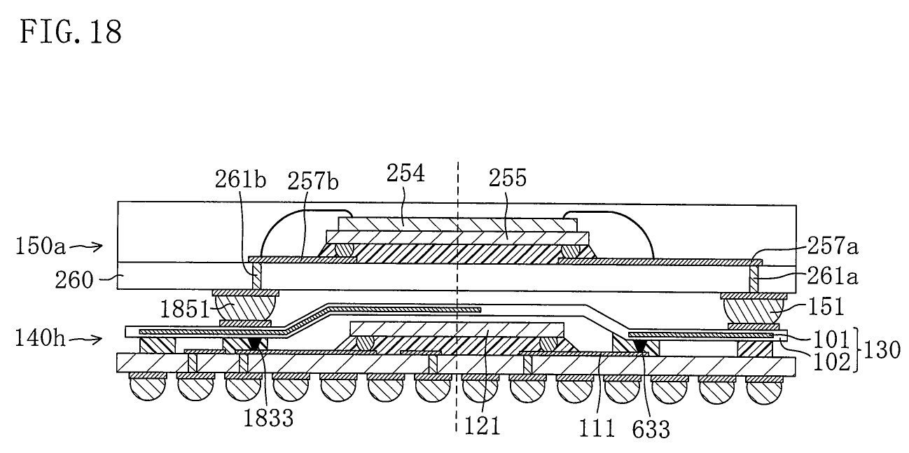

FIG. 18 is a cross-sectional view of an example PoP semiconductor device of this embodiment.

The semiconductor device of this embodiment has a structure in which an upper package 150a is stacked on a lower package 140h.

In the example semiconductor device of this embodiment, wiring paths from a semiconductor chip 121 of the lower package 140h to semiconductor chips 254 and 255 of the upper package 150a can be caused to be shorter than those of the semiconductor device of the first embodiment of FIG. 1A. By providing the shorter wiring paths, impedance essential for a power source or the like can be reduced. This will be hereinafter described.

In the case of the semiconductor device of the first embodiment of FIG. 1A, the upper and lower packages are electrically connected via the solder balls 151 provided on the peripheral portion of the semiconductor device. FIG. 18 shows a path of this embodiment similar to that of the first embodiment on a right side thereof. Specifically, this path electrically connects from the semiconductor chip 121 through a front-surface substrate wiring 111, a gold bump 633, a tape substrate wiring 101, a solder ball 151, a via hole 261a penetrating through a resin substrate 260 of an upper package 150a, a substrate wiring 257a extended to a peripheral portion of the upper package 150a, and the like in this stated order, to the semiconductor chips 254 and 255 of the upper package. This path is once extended to a position between the solder ball 151 and the gold bump 633 and thereafter is extended back.

A path of a wiring shorter than the aforementioned path in the semiconductor device of this embodiment is shown on a left side of FIG. 18. Specifically, this path electrically connects from the semiconductor chip 121 through a front-surface substrate wiring 111, a gold bump 1833, a solder ball 1851 provided above a gold bump 1833, a via hole 261b that is provided above the solder ball 1851 and closer to the semiconductor chips 254 and 255 than the via hole 261a, a substrate wiring 257b shorter than the substrate wiring 257a, and the like in this stated order, to the semiconductor chip 254 and 255.

Thus, a wiring path that is shorter than when the upper and lower packages are connected at a peripheral portion of the tape substrate 130 can be provided, resulting in lower impedance of the wiring path. Also, the solder ball 1851 used in this path has a lower effect of avoiding poor contact due to deformation of the tape substrate 130 than the solder ball 151. However, the solder ball 1851 is provided farther inside the semiconductor device than the solder ball 151, so that the solder ball 1851 is less affected by warpage of the upper and lower packages, and therefore, the poor contact problem is less likely to occur.

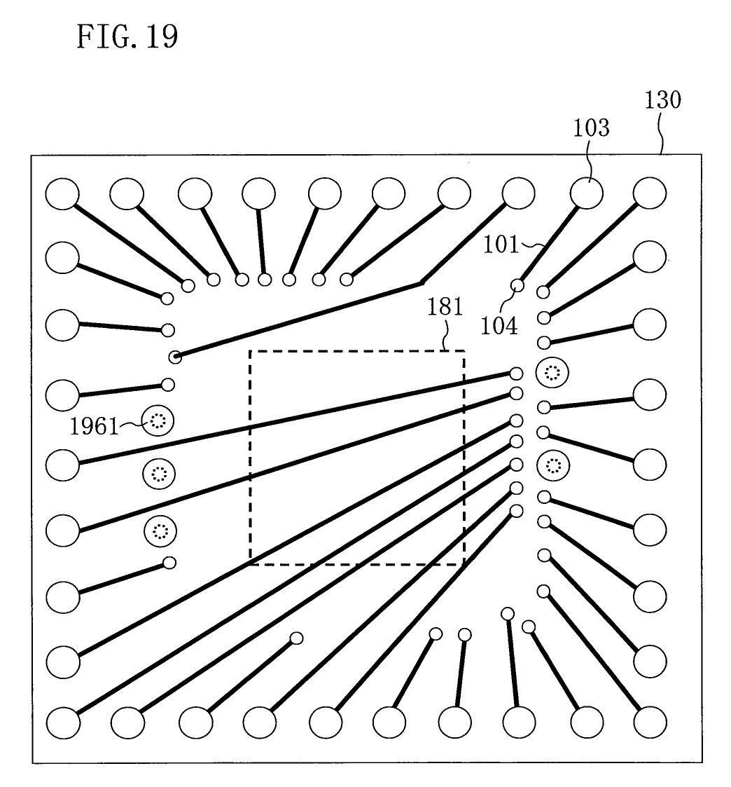

FIG. 19 is a plan view of the tape substrate 130, showing an arrangement 1961 of the gold bumps 1833 and the solder balls 1851.

Note that, in the conventional PoP semiconductor device, as shown in FIG. 23, the presence of the surface substrate wiring 11 on the resin substrate 20 makes it difficult to shift the solder ball 51 to the inside of the semiconductor device. Therefore, the upper package of the PoP semiconductor device is already standardized so that solder balls are arranged at predetermined positions on a periphery of the package. Therefore, coordination with the upper package 150a is required so as to customize the solder ball 1851 so that it is provided closer to the inside as in this embodiment, thereby improving electrical characteristics.

### Tenth Embodiment

Hereinafter, a tenth embodiment will be described. In this embodiment, a flat tape substrate is used, thereby increasing the flexibility of arrangement of solder balls for connecting the tape substrate and an upper package. Therefore, the number of signal connections between the upper and lower packages can be increased. This embodiment will be hereinafter described in greater detail.

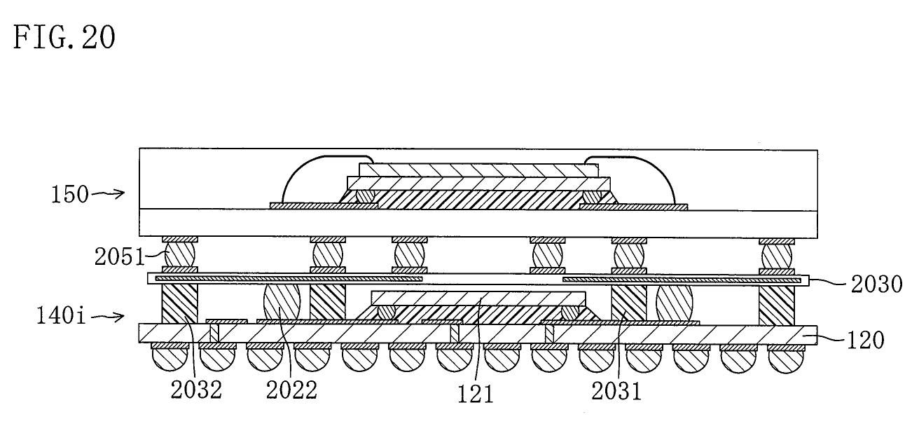

FIG. 20 is a cross-sectional view of an example PoP semiconductor device of this embodiment.

The example semiconductor device of this embodiment has a structure in which an upper package 150 is stacked on a lower package 140i with solder balls 2051 being interposed therebetween, which is similar to the semiconductor device of the first embodiment of FIG. 1A. Here, the upper package 150 has the same structure as that of the first embodiment. The lower package 140i will be hereinafter described, mainly indicating a difference from the lower package 140 of the first embodiment.

Firstly, the tape substrate 130 of first embodiment protrudes toward the upper package 150 at a portion thereof above the semiconductor chip 121, and is close to the resin substrate 120 at the other portions thereof (a peripheral portion of the semiconductor device, etc.).

By contrast, a tape substrate 2030 of this embodiment has a flat structure that does not have a protrusion as described above. Therefore, as is different from the first embodiment, a distance between the resin substrate 120 and the tape substrate 2030 is uniform no matter where it is measured, i.e., above the semiconductor chip 121 and the other portions. Since the tape substrate 2030 and the resin substrate 120 are connected in this manner, a solder ball 2022, an adhesive sheet 2031 and an elastic adhesive sheet 2032 in this embodiment all have a size that causes them to be higher than an upper surface of the semiconductor chip 121.

Thus, the tape substrate 2030 is flat and is parallel to the resin substrate 120. Therefore, an overall height of the upper and lower packages is large as compared to other embodiments, however, the solder balls 2051 can be arranged at any positions, so that the number of signal connections between the upper and lower packages can be advantageously increased.

Also, in the case of the first embodiment, the height of the upper surface of the tape substrate 130 varies depending on the position, i.e., above the semiconductor chip 121 and above the other portions, so that the solder balls 151 have a size that can compensate for this difference. However, this is not required for this embodiment, in which a size of the solder ball 2051 can be reduced to decrease a pitch of arrangement. Note that an excessive reduction in the size of a solder ball makes it difficult to maintain the tape substrate 2030 parallel to the resin substrate 120, and thus it is necessary to separately appropriately set the sizes of solder balls so as to connect the upper and lower packages.

Also, poor connection due to warpage of the upper and lower packages at the solder balls 2051 provided on a peripheral portion of the semiconductor device is avoided by deformation of the tape substrate 2030 and an elastic adhesive sheet 2132. This is similar to the first embodiment. Also, poor connection at the solder balls 2051 inside the semiconductor device is suppressed since warpage of the packages is smaller than that of the peripheral portion. Note that since parameters vary depending on the material, shape and the like of each component, evaluation needs to be conducted individually.

### Eleventh Embodiment

Hereinafter, an eleventh embodiment will be described. In this embodiment, a tape substrate including a plurality of layers is used to support more complicated connection between upper and lower packages.

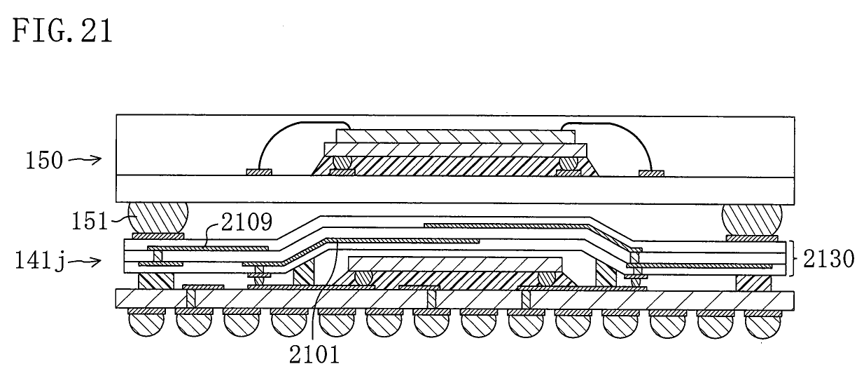

FIG. 21 is a cross-sectional view of an example PoP semiconductor device of this embodiment.

The example semiconductor device of this embodiment has a structure in which an upper package 150 is stacked on a lower package 140j with solder balls 151 being interposed therebetween, which is similar to the semiconductor device of the first embodiment of FIG. 1A. Here, the upper package 150 has the same structure as that of the first embodiment.

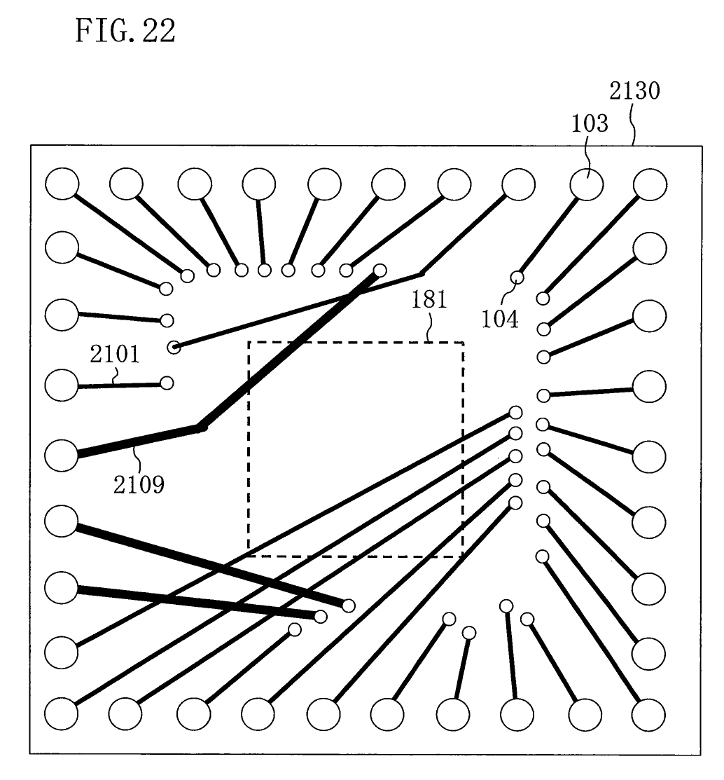

A tape substrate 2130 provided in the lower package 140j of this embodiment includes a plurality of layers of tape substrate wirings. Therefore, as can also seen from FIG. 22 that is a plan view of the tape substrate 2130, a plurality of tape substrate wirings can be divided into lower-layer tape substrate wirings 2101 and upper-layer tape substrate wirings 2109, which can be separately extended, intersecting without being electrically connected to each other. Thus, by providing a multilayer tape substrate, wirings can be extended in a more complicated manner.

### Twelfth Embodiment

Hereinafter, a twelfth embodiment will be described. In this embodiment, a metal fine line is used instead of a tape substrate, resulting in lower cost.

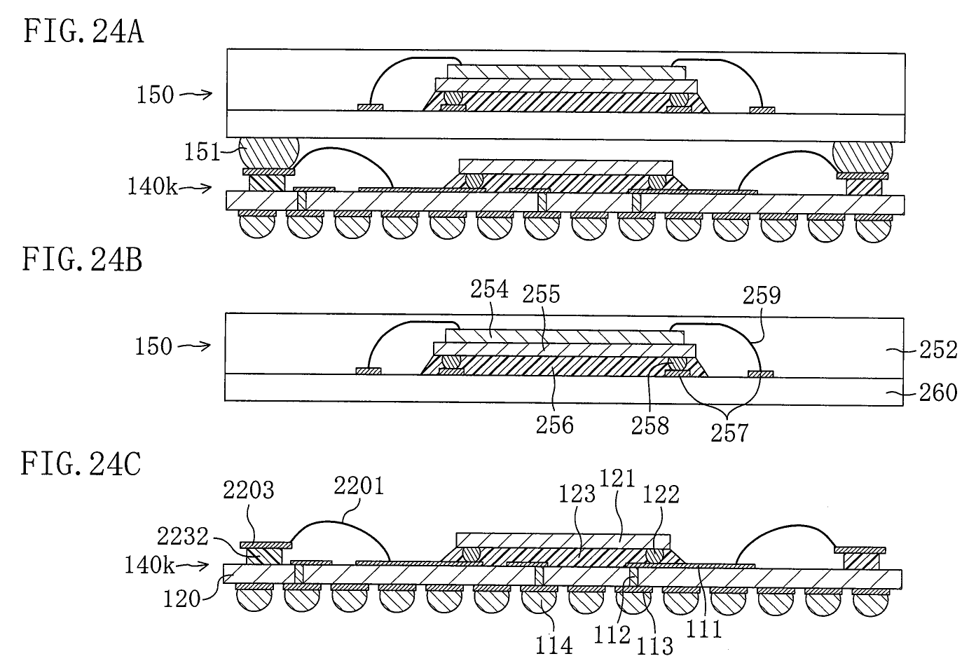

FIG. 24A is a cross-sectional view of an example PoP semiconductor device of this embodiment.

The example semiconductor device of this embodiment has a structure in which an upper package 150 (FIG. 24B) is stacked on a lower package 140k (FIG. 24C) with solder balls 151 being interposed therebetween, which is similar to the semiconductor device of the first embodiment of FIG. 1A. Here, the upper package 150 has the same structure as that of the first embodiment.

The lower package 140k of this embodiment is different from the lower package 140 of the first embodiment in that the lower package 140k does not include the tape substrate 130 (the tape substrate wirings 101 and the polyimide resin layer 102), the rear surface copper pad 104, the adhesive sheet 131, or the solder ball 133.

On the other hand, the lower package 140k includes electrically conductive pads 2203 provided on a resin substrate 120 with an adhesive material 2232 being interposed therebetween. Also, metal fine wires 2201 are provided for electrically connecting the electrically conductive pads 2203 and front-surface substrate wirings 111. The other parts of the lower package 140k are similar to those of the lower package 140 of the first embodiment.

Also, the solder balls 151 for stacking the upper package 150 on the lower package 140k are provided on the electrically conductive pads 2203 of the lower package 140k. Therefore, the upper package 150 is electrically connected via the solder balls 151 and the electrically conductive pad 2203 to the metal fine wires 2201, and is also electrically connected via the front-surface substrate wirings 111 and the like to the semiconductor chip 121.

Note that the metal fine wires 2201 may be electrically connected via via holes 112, and rear-surface substrate wirings 113 to solder balls 114 on a rear surface of the resin substrate 120. Also, for example, when the semiconductor chip 121 is mounted by wire bonding (see the second embodiment of FIG. 4 or the like), the electrically conductive pads 2203 and the semiconductor chip 121 may be connected via the metal fine wires 2201 (without via the front-surface substrate wirings 111).

Also in the aforementioned structure, the metal fine wires 2201 form wiring paths different from wirings in the resin substrate 120 (the front surface substrate wirings 111, the rear surface substrate wirings 113 and the like). Therefore, as in the other embodiments, a wiring path in the resin substrate 120 can be simplified, resulting in lower cost, a shorter design period, prevention of an increase in height of a PoP semiconductor device, and the like.

Also, when an elastic adhesive material 2232 is used, then even if the upper and lower packages warp in opposite directions, the solder balls 151 can freely move within a range that allows the adhesive material 2232 to deform. Therefore, poor connection of the solder balls 151 can be reduced.

What is claimed is:

1. A semiconductor device comprising:
a substrate having a substrate wiring;
a semiconductor chip provided on the substrate;
a first electrical conductor electrically connecting the semiconductor chip and the substrate wiring;
an electrically conductive pad provided on the substrate; and
a wiring member electrically connected to the electrically conductive pad and serving as a wiring path different from the substrate wiring.

2. The semiconductor device of claim 1, further comprising:
a tape substrate having a tape substrate wiring and an insulating layer sandwiching the tape substrate wiring and provided on the substrate and the semiconductor chip; and
a second electrical conductor electrically conducting the tape substrate wiring and the substrate wiring,
wherein the wiring member is the tape substrate wiring, and
the electrically conductive pad is provided on the tape substrate and is electrically connected to the tape substrate wiring.

3. The semiconductor device of claim 1, wherein
the wiring member is a metal fine wire.

4. The semiconductor device of claim 1, wherein
an elastic adhesive material is provided between the substrate and the electrically conductive pad.

5. The semiconductor device of claim 1, wherein
the semiconductor chip is fixed onto the substrate using a paste or a sealing resin.

6. The semiconductor device of claim 2, further comprising:
an adhesive or an adhesive sheet attaching the substrate and the tape substrate, the adhesive or adhesive sheet being provided in at least one of a region between the semiconductor chip and the second electrical conductor and a region between the second electrical conductor and the elastic adhesive material.

7. The semiconductor device of claim 1, wherein
the first electrical conductor is a bonding wire connecting the semiconductor chip and the substrate wiring, and
the semiconductor device further comprises a sealing resin sealing the semiconductor chip and the bonding wire.

8. The semiconductor device of claim 2, further comprising:
at least another semiconductor chip provided on the semiconductor chip;
a bonding wire connecting the at least another semiconductor chip and the substrate wiring; and
a sealing resin sealing the semiconductor chip, the at least another semiconductor chip and the bonding wire,
wherein the elastic adhesive material and the second electrical conductor are set to have a height depending on the presence of the at least another semiconductor chip.

9. The semiconductor device of claim 2, further comprising:
an adhesive or an adhesive sheet attaching the substrate and the tape substrate and provided in a region including a position of the second electrical conductor,
wherein the second electrical conductor is provided on the tape substrate and is convex toward the substrate, and penetrates through the adhesive or the adhesive sheet to electrically connect to the substrate wiring.

10. The semiconductor device of claim 2, further comprising:
an adhesive or an adhesive sheet attaching the substrate and the tape substrate and provided in a region including a position of the second electrical conductor,
wherein the second electrical conductor is provided on the substrate and is convex toward the tape substrate, and penetrates through the adhesive or the adhesive sheet to electrically connect to the tape substrate wiring.

11. The semiconductor device of claim 2, further comprising:
at least one hole penetrating through a portion of the tape substrate closer to the semiconductor chip than the second electrical conductor,
wherein a sealing resin is injected between the substrate and the tape substrate.

12. The semiconductor device of claim 6, further comprising:
a plurality of holes penetrating through at least one of a portion of the tape substrate closer to the semiconductor chip than the adhesive or adhesive sheet and a portion of the tape substrate between the adhesive or adhesive sheet and the elastic adhesive material.

13. The semiconductor device of claim 9, further comprising:
a plurality of holes penetrating through at least one of a portion of the tape substrate closer to the semiconductor chip than the adhesive or adhesive sheet and a portion of the tape substrate between the adhesive or adhesive sheet and the elastic adhesive material.

14. The semiconductor device of claim 10, further comprising:
a plurality of holes penetrating through at least one of a portion of the tape substrate closer to the semiconductor chip than the adhesive or adhesive sheet and a portion of the tape substrate between the adhesive or adhesive sheet and the elastic adhesive material.

15. The semiconductor device of claim 2, further comprising:
a dummy wiring provided in the tape substrate, circumventing the tape wiring and extending from a region on the semiconductor chip to a peripheral portion of the tape substrate; and
a heat conductor connecting an upper surface of the semiconductor chip and the dummy wiring.

16. The semiconductor device of claim 2, wherein
the electrically conductive pad is provided on the second electrical conductor.

17. The semiconductor device of claim 2, wherein
the elastic adhesive material and the second electrical conductor have a thickness higher than an upper surface of the semiconductor chip.

18. The semiconductor device of claim 2, wherein
the tape substrate further includes another tape wiring and another insulating layer to have a multilayer structure having two or more layers.

19. The semiconductor device of claim 2, wherein
a package including a second substrate on which a second semiconductor chip is provided is provided above the substrate, and
the electrically conductive pad and the second semiconductor chip are electrically connected.

20. A method for manufacturing a semiconductor device, comprising the steps of:
(a) providing a semiconductor chip on a substrate having a substrate wiring; and
(b) providing a tape substrate having a tape wiring sandwiched by an insulating layer, on the substrate and the semiconductor chip,
wherein step (a) includes electrically connecting the substrate wiring and the semiconductor chip via a first electrical conductor,
step (b) includes electrically connecting the substrate wiring and the tape wiring via a second electrical conductor, and attaching the tape substrate and the substrate using an adhesive material, and
an electrically conductive pad connected to the tape wiring is provided on a side opposite to the substrate of the tape wiring.

21. A method for manufacturing a semiconductor device, comprising the steps of:
providing a semiconductor chip on a substrate having a substrate wiring; and
providing, on the substrate, an electrically conductive pad, and a wiring member electrically connected to the electrically conductive pad and serving as a wiring path different from the substrate wiring.
